(19) United States
(12) Patent Application Publication
(10) Pub. No.: US 2004/0188712 A1
(43) Pub. Date: Sep. 30, 2004

(54) Heterojunction bipolar transistor having non-uniformly doped collector for improved safe-operating area

(75) Inventors: Chien Ping Lee, Fremont, CA (US); Frank Hin Fai Chau, Fremont, CA (US); Nanlei Larry Wang, Palo Alto, CA (US); Clarence John Dunnrowicz, Santa Cruz, CA (US); Yan Chen, Fremont, CA (US); Barry Jia-Fu Lin, Cupertino, CA (US)

Correspondence Address: BEYER WEAVER & THOMAS LLP, P.O. BOX 778, BERKELEY, CA, 94704-0778, US

(73) Assignee: EiC Corporation, Fremont, CA

(21) Appl. No.: 10/820,343

(22) Filed: Apr. 7, 2004

Related U.S. Application Data
(63) Continuation-in-part of application No. 10/267,215, filed on Oct. 8, 2002.

(51) Int. Cl. H01L 31/0328

(52) U.S. Cl. 257/197; 257/198

(57) ABSTRACT

The safe-operating area (SOA) in a heterojunction bipolar transistor (HBT) is improved by providing a collector region in the transistor having a graded (continuous or stepped) doping between the base region and the underlying subcollector region with the collector doping being lowest near the base and highest near the subcollector and with the collector doping being less than the doping of the subcollector. The non-uniformly doped collector reduces Kirk effect induced breakdown when collector current increases.

### CROSS REFERENCE TO RELATED APPLICATIONS

This application is a continuation in part of copending application Ser. No. 10/267,215 filed Oct. 8, 2002.

### BACKGROUND OF THE INVENTION

This invention relates generally to heterojunction bipolar transistors (HBT), and more particularly the invention relates to improving the safe-operating area (SOA) of such a transistor.

Heterojunction bipolar transistors (e.g., III-V compound semiconductor) are used in amplifier circuits for telecommunications applications. A major concern lies in operating the transistors in safe-operating areas (SOA) to prevent overdrive and failure of the devices. As shown in FIG. 1, the SOA is defined by two boundaries. The first boundary, SOA Boundary I, is limited by the open-emitter base-collector junction breakdown voltage, BVcbo of the transistor. This boundary sets the operating limit of the transistor at low current densities. The second boundary, SOA Boundary II, is related to the collector breakdown when substantial injected current carriers are present in the collector. This boundary is important at medium to high current levels. If one attempts to operate a HBT beyond the SOA boundaries in the non-safe operating areas as shown in the figure, the device will catastrophically fail. The conventional way to increase the collector breakdown voltage is to increase the thickness and to decrease the doping concentration of the collector. Using the approach conventional HBTs have been produced with a BVcbo of around 70 volts by using a collector with a thickness of 3 μm and a dopant concentration of 6e15 cm⁻³. However, although a larger BVcbo moves SOA Boundary I to a higher Vce, the SOA Boundary II does not necessarily move to a higher collector current, Ic. In fact, breakdown always happens at a voltage smaller than BVcbo when there is large current flowing through the transistor. This is a result of the Kirk effect.

The Kirk effect results when the collector current increases to a high enough level and the number of injected electrons compensates the space charge in the collector and changes the electric field distribution. The effect happens when the effective injected charge density exceeds the background doping concentration in the collector, and the space charge changes sign and the location of the high field region moves from the base-collector junction to the collector-subcollector junction. The breakdown then is no longer controlled by the doping density in the collector alone, but also by the collector current. As Ic increases, the effective negative space charge density increases, and this causes the electric field to increase at the collector-subcollector junction, and results in a reduction of breakdown voltage. Further, decreasing of the collector doping will only improve the low current breakdown voltage but will not improve the medium and high current breakdown voltage.

### BRIEF SUMMARY OF THE INVENTION

The standard heterojunction bipolar transistor has a uniformly doped collector. In accordance with the present invention, the collector of a heterojunction bipolar transistor has a non-uniform doping with the doping near the base region being more lightly doped than the subcollector side of the collector. The doping profile can have a plurality of distinctly doped layers or a continuous grading of the collector doping increasing from base region to subcollector region.

The invention and objects and features thereof will be more readily apparent from the following detailed description and appended claims when taken with the drawings.

### BRIEF DESCRIPTION OF THE DRAWINGS

FIG. 1 is a graph of collector current, Ic, versus collector-emitter voltage, Vce, for a HBT which illustrates safe operation boundaries.

FIG. 2 is a section view of a HBT which is modified in accordance with an embodiment of the invention.

FIG. 3 illustrates SOA boundaries in plots of Ic versus Vbc for a transistor with a standard uniformly doped collector and for three transistors with non-uniform doping in accordance with the invention.

FIG. 4 is a section view of a HBT which is modified in accordance with another embodiment of the invention.

FIG. 5 illustrates SOA boundaries in plots of collector current, Ic, versus collector-emitter voltage, Vce, for a conventional HBT and for two HBTs in accordance with the invention.

FIG. 6 illustrates the use of a plurality of distinctly doped layers of collector doping concentration increasing from base region to subcollector region in a HBT in accordance with another embodiment of the invention.

FIG. 7 illustrates the use of a continuous grading of the collector doping concentration increasing from base region to subcollector region in a HBT in accordance with another embodiment of the invention.

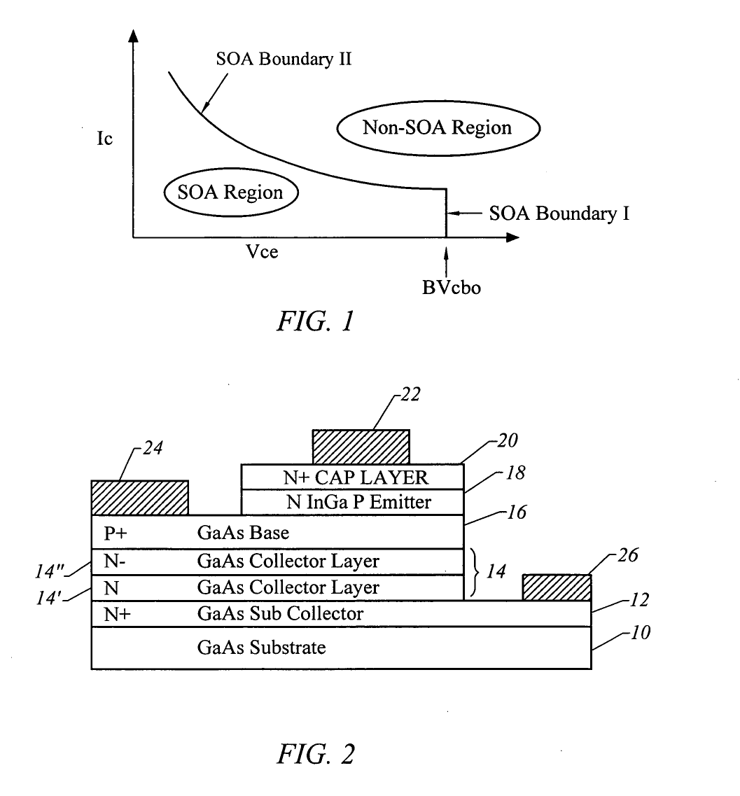

### DETAILED DESCRIPTION OF THE INVENTION

FIG. 2 is a section view of a heterojunction bipolar transistor which is modified in accordance with one embodiment of the invention. The transistor comprises a GaAs substrate 10 on which is formed an N⁺ doped GaAs subcollector region 12 and a N doped GaAs collector 14 which includes an N doped layer 14′ and N⁻ doped layer 14″ which abuts a P⁺ GaAs base 16. An N doped InGaAs emitter 18 is formed on base 16 with an N⁺ cap layer 20 formed on emitter 18. Cap layer 20 can comprise an N⁺ doped GaAs layer with an N⁺ InGaAs layer thereon. Contacts 22, 24, and 26 are formed on the emitter, base, and collector, respectively.

Since the Kirk effect induced breakdown happens near the collector-subcollector junction, the provision of non-uniform doping as illustrated in FIG. 2 with increased doping concentration in the collector near the subcollector layer will mitigate the effect. However, to have an optimum design, one has to be careful not to make the more heavily doped collector layer too thick or use a doping concentration close to that in the heavily doped subcollector layer. Otherwise, BVcbo and therefore the SOA boundary I will suffer.

Table I illustrates four collector structures and the respective calculated breakdown voltage. Collectors made of GaAs are assumed in the calculation. The standard structure has a uniformly doped collector, which one would normally use to have a high breakdown voltage. The other three collector structures, A, B, and C, all have non-uniform collector doping profiles, and each has a more heavily doped layer inserted in the subcollector side of the collector layer. The differences among the three structures, A, B, and C, are in the thickness of the low and high doped layers and the doping concentration in the high doped layer. All four structures have the same total collector thickness of 3 μm. The same emitter size of 24 μm² is used in the calculation. A constant breakdown field is assumed, and when the electric field reaches its value, the device fails because the collector breakdown and the SOA boundaries are closely related to each other. The BVcbo decreases when a more heavily doped layer is included in the collector near the subcollector region. However, if the layer is kept thin relative to the total collector thickness, and its doping level remains low relative to the subcollector doping which is typically on the order of 10¹⁸ ions cm⁻³, the decrease in BVcbo is minimal since a large portion of the collector close to the base remains at low doping level. The breakdown induced by the Kirk effect, however, changes drastically with changes in the collector structure. At Ic=10 mA, for example, one can see that the breakdown voltage can be increased by more than a factor of two if a proper structure is used.

TABLE 1

| | Standard Structure | Structure A | Structure B | Structure C |
|---|---|---|---|---|
| Collector | 3.0 μm, 7e15 cm⁻³ | 2.5 μm, 7e15 cm⁻³ + | 2.5 μm, 7e15 cm⁻³ + | 2.0 μm, 7e15 cm⁻³ + |
| Structure | | 0.5 μm, 2e16 cm⁻³ | 0.5 μm, 4e16 cm⁻³ | 1.0 μm, 4e16cm⁻³ |
| BVcbo | 80 V | 78 V | 75.6 V | 67 V |
| BV at 10 mA | 21.5 V | 29.5 V | 42.7 V | 62.7 V |

BV = Breakdown Voltage

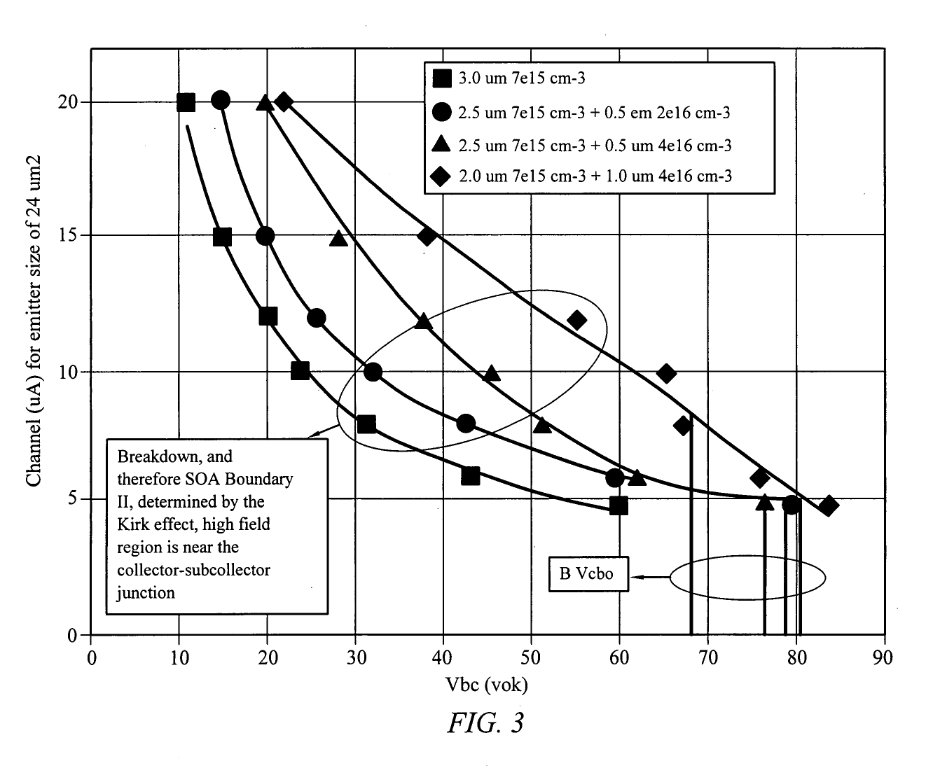

FIG. 3 shows the SOA (breakdown voltage as a function of IC) of the four devices. A great improvement in SOA Boundary II is obtained by using the invention illustrated in these embodiments. An added advantage for these structures is the reduced on resistance when the devices are in saturation because of the higher doping in the collector region near the subcollector layer.

While a two-step, low high collector doping profile is used in these embodiments, other embodiments can realize the non-uniform collector doping profile for the improvement of SOA Boundary II. For example, one can use multiple layers in the collector instead of two doping layers. The layer with the lowest doping concentration is near the base, and that with the highest doping concentration is near the subcollector which has the highest doping level.

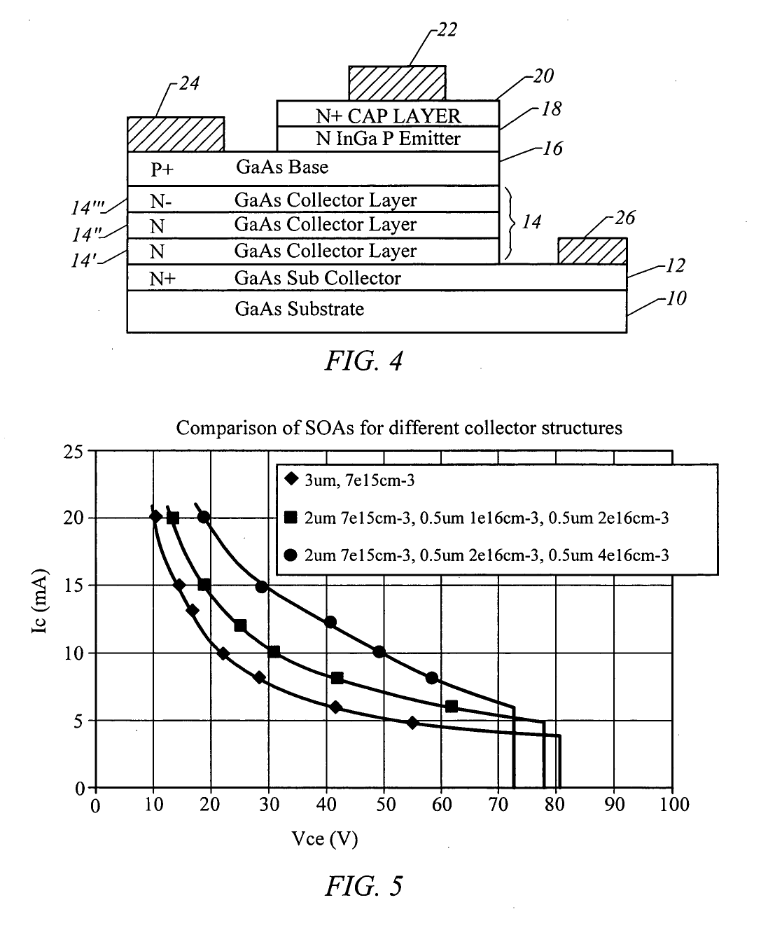

FIG. 4 is a section view of a HBT in accordance with another embodiment of the invention similar to the embodiment of FIG. 2 but in which the collector 14 comprises three doped layers 14′, 14″ and 14′″ of decreasing dopant concentration toward the base layer 16. All other elements in FIG. 4 have the same reference numbers as in FIG. 2. Here, layer 14′″ abutting base 16 has the lowest dopant concentration and layer 14′ abutting subcollector 12 has the highest dopant concentration.

FIG. 5 is a plot of calculated SOA boundaries, for a HBT having a collector of 3 micron thickness and a uniform dopant concentration of 7e15 cm⁻³ and for two embodiments of the invention as shown in FIG. 4. In one embodiment collector region 14′ is 0.5 micron in thickness and has 4e16 cm⁻³ doping, collector region 14″ is 0.5 micron in thickness with 2e16 cm⁻³ doping, and collector region 14′″ is 2 microns in thickness and 7e15 cm⁻³ doping. In the other embodiment, collector region 14′ is 0.5 micron in thickness and has 2e16 cm⁻³ doping, collector region 14″ is 0.5 micron in thickness and has 1e16 cm⁻³ doping, and collector region 14′″ is 2 microns in thickness and has 7e15 cm⁻³ doping. In both embodiments, the subcollector doping is again on the order of 1-5e18 cm⁻³ doping. It is noted that SOA Boundary II moves to higher collector current for two embodiments of the invention as compared to the collector structure having a uniform dopant concentration.

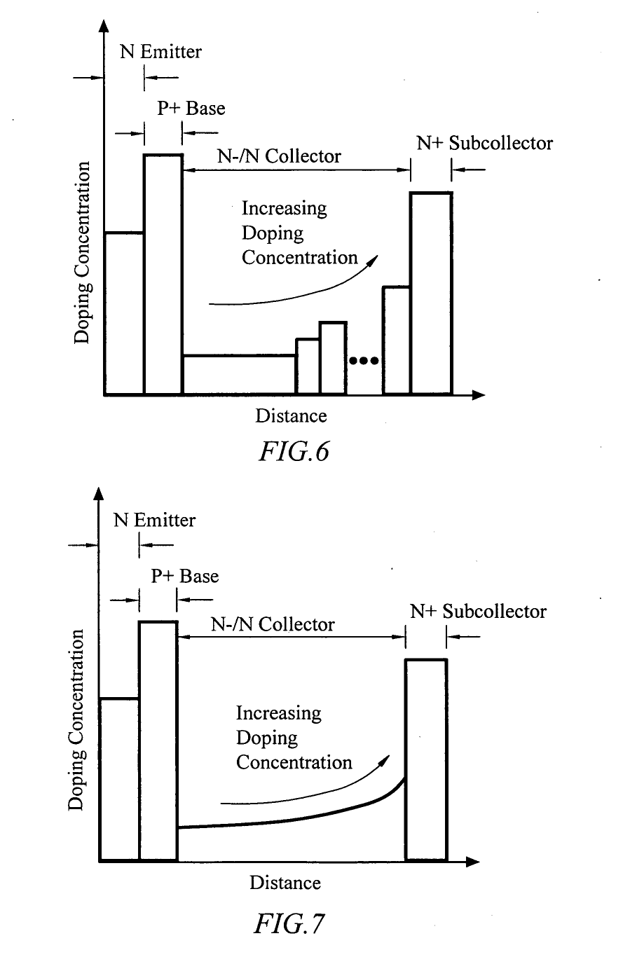

The invention can be generalized to have the collector region comprising three or more distinctly doped layers with doping concentration increasing in steps from the base side to the subcollector side of the collector region. This is illustrated in FIG. 6.

Alternatively, a continuous grading in the collector doping profile can be used to improve SOA Boundary II. Here the collector doping profile increases from the base region to the subcollector region and can have a structure as shown in FIG. 7 with a dopant range as shown in Table 1 or FIG. 5 but without distinctly doped layers. The doping concentration increases continuously rather than in steps. The key for the improvement of SOA boundary II is to have the more heavily doped collector region near the subcollector layer and the more lightly doped region near the base, and the heaviest doping concentration in the collector layer remains lower than that in the subcollector layer.

The invention can be applied to all heterojunction bipolar transistors, including for example, AlGaAs/GaAs, InGaP/GaAs, InP/InGaAs, InAlAs/InGaAs, and InAlGaAs/InGaAs single and double heterojunction bipolar transistors with GaAs, InGaAs, InP, AlGaAs, InGaP, InAlAs, or a combination thereof as the collector material. The invention can be also applied to Si based bipolar transistors including Si/SiGe heterojunction bipolar transistors.

While the invention has been described with reference to specific embodiments, the description is illustrative of the invention and is not to be construed as limiting the invention. Various modifications and applications may occur to those skilled in the art without departing from the true spirit and scope of the invention as defined by the appended claims.

What is claimed is:

1. A heterojunction bipolar transistor (HBT) comprising:
a) an emitter region of one conductivity type,
b) a base region of opposite conductivity type abutting the emitter region,
c) a collector region of the one conductivity type abutting the base region, the collector region comprising at least three layers having decreasing dopant concentrations toward the base region, the layer in the collector region abutting the base region having the lowest dopant concentration, and
d) a subcollector region of the one conductivity type abutting the collector region, the collector region having a non-uniform doping with lightest doping near the base region and heaviest doping near the subcollector region, the heaviest doping being less than the doping in the subcollector region.

2. The HBT as defined by claim 1 wherein the layer in the collector region abutting the base region is thicker than the other two or more layers in the collector region.

3. The HBT as defined by claim 2 wherein the layer in the collector region abutting the base region has a dopant concentration on the order of 7e15 cm⁻³ and the layer in the collector region abutting the subcollector region has a dopant concentration on the order of 2-4e16 cm⁻³.

4. The HBT as defined by claim 3 wherein the subcollector has a dopant concentration on the order of 1-5e18 cm⁻³.

5. The HBT as defined by claim 4 wherein the middle layer or layers in the collector region has or have a dopant concentration on the order of 1-2e16 cm⁻³.

6. The HBT as defined by claim 5 wherein the layer in the collector layer abutting the base region is on the order of 2 microns in thickness and the other two or more layers in the collector region are each on the order of 0.5 microns in thickness.

7. The HBT as defined by claim 2 wherein the layer in the collector region abutting the base region is on the order of 2 microns in thickness and the other two or more layers in the collector region are each on the order of 0.5 microns in thickness.

8. A heterojunction bipolar transistor (HBT) having improved safe-operating area characterized by a collector region between a base region and a subcollector region, the collector region having at least three layers of one conductivity type and decreasing dopant concentrations toward the base region, the layer in the collector region abutting the base region having the lowest dopant concentration.

9. The HBT as defined by claim 8 wherein the layer in the collector region abutting the base region is thicker than the other two or more layers in the collector region.

10. The HBT as defined by claim 9 wherein the layer in the collector region abutting the base region has a dopant concentration on the order of 7e15 cm⁻³ and the layer in the collector region abutting the subcollector region has a dopant concentration on the order of 2-4e16 cm⁻³.

11. The HBT as defined by claim 10 wherein the middle layer or layers in the collector region has or have a dopant concentration on the order of 1-2e16 cm⁻³.

12. The HBT as defined by claim 11 wherein the subcollector has a dopant concentration on the order of 1-5e18 cm⁻³.

13. The HBT as defined by claim 12 wherein the one conductivity type is N type.

14. The HBT as defined by claim 8 wherein the one conductivity type is N type.

15. A heterojunction bipolar transistor (HBT) comprising:
a) an emitter region of one conductivity type,
b) a base region of opposite conductivity type abutting the emitter region,
c) a collector region of the one conductivity type abutting the base region, and
d) a subcollector region of the one conductivity type abutting the collector region, the collector region having a continuously increasing doping concentration toward the subcollector region with the lightest doping near the base region and the heaviest doping near the subcollector region, the heaviest doping being less than the doping in the subcollector region.
